(19) United States
(12) Patent Application Publication
(10) Pub. No.: US 2026/0023109 A1
(43) Pub. Date: Jan. 22, 2026

(54) BRIDGE BEAM, SEMICONDUCTOR DEVICE HANDLING APPARATUS, AND SEMICONDUCTOR DEVICE TESTING APPARATUS

(71) Applicant: ADVANTEST Corporation, Tokyo (JP)

(72) Inventors: Aritomo Kikuchi, Tokyo (JP); Hubert Werkmann, Munich (DE)

(73) Assignee: ADVANTEST Corporation, Tokyo (JP)

(21) Appl. No.: 19/272,401

(22) Filed: Jul. 17, 2025

(30) Foreign Application Priority Data
Jul. 17, 2024 (JP) 2024-114339

(51) Int. Cl. G01R 31/28; G01R 31/311

(52) U.S. Cl. CPC G01R 31/2865; G01R 31/2863; G01R 31/2868; G01R 31/311

(57) ABSTRACT

A bridge beam attached to a semiconductor device handling apparatus that handles a semiconductor device, includes a beam-shaped main body to which a probe card is attached. The probe card has a contact that is electrically connected to a terminal of the semiconductor device. The bridge beam includes a first actuator, attached to the beam-shaped main body, that moves an optical probe relative to the semiconductor device. The optical probe performs one or both of emitting an optical signal to the semiconductor device and receiving the optical signal from the semiconductor device.

### CROSS-REFERENCE TO RELATED APPLICATIONS

The present application claims priority to Japanese Patent Application No. 2024-114339 filed on Jul. 17, 2024. The contents of this application are incorporated herein by reference in their entirety.

### BACKGROUND

### Technical Field

The present invention relates to a bridge beam attached to a semiconductor device handling apparatus that handles a device under test (hereinafter simply referred to as a “DUT” (Device Under Test)) such as a semiconductor integrated circuit element, a semiconductor device handling apparatus including the bridge beam, and a semiconductor device testing apparatus including the semiconductor device handling apparatus.

### Discussion of the Background

As a testing apparatus necessary for testing chips at a wafer level, there has been known a testing apparatus that includes a wafer prober and a wafer tester having a contact module (probe card) (for example, see Patent Document 1). The contact module is used to connect a device side interface of the wafer tester to interfaces of chips on a wafer fixed to the wafer prober.

A chip including an optoelectronic integrated circuit has a contact pad as an electrical interface and a grating coupler or the like as an optical interface. For testing on a wafer level of such chips, the contact module described above has a needle for contacting the contact pad of the chip and an optical interface that can be assigned to a grating coupler or the like.

The wafer as described above is fixed to a positioning stage of the wafer prober, and the positioning stage performs positioning of the contact pad relative to the needle and positioning of the optical interface relative to the grating coupler or the like.

### PATENT DOCUMENT

Patent Document 1: JP 2024-514646 A

In the known technology described above, when the positioning stage to which the wafer is fixed is driven, the relative position of the contact pad with respect to the needle and the relative position of the optical interface with respect to an optical deflection element change simultaneously, and it is not possible to change only the relative position of the optical interface with respect to the optical deflection element, and thus it may not be possible to position the optical interface relative to the optical deflection element with high precision.

### SUMMARY

One or more embodiments provide a bridge beam, a semiconductor device handling apparatus, and a semiconductor device testing apparatus that are capable of positioning an optical probe with respect to a semiconductor device with high precision.

Aspect 1 of one or more embodiments is a bridge beam attached to a semiconductor device handling apparatus that handles a semiconductor device. The bridge beam includes a beam-shaped main body portion on which a probe card having a contact electrically connected to a terminal of the semiconductor device is attached; and a first actuator that is attached to the main body portion and moves an optical probe relative to the semiconductor device, the optical probe emitting an optical signal to the semiconductor device and/or the optical signal being incident on the optical probe.

In accordance with Aspect 2 of one or more embodiments, in the bridge beam of Aspect 1, the bridge beam may further include a holder that is attached to the first actuator and holds the optical probe.

In accordance with Aspect 3 of one or more embodiments, in the bridge beam of Aspect 1 or 2, the bridge beam may further include an optical detection portion that detects the optical signal emitted from the optical probe; and the optical detection portion may output a detection result to a calculation device that calculates an intensity of the optical signal based on the detection result of the optical detection portion.

In accordance with Aspect 4 of one or more embodiments, in the bridge beam of Aspect 3, the bridge beam may further include a second actuator that moves the optical detection portion relative to the optical probe to move the optical detection portion to a position where the optical signal is allowed to be received.

In accordance with Aspect 5 of one or more embodiments, in the bridge beam of any one of Aspects 1 to 4, the bridge beam may further include the optical probe.

In accordance with Aspect 6 of one or more embodiments, in the bridge beam of any one of Aspects 1 to 4, the first actuator may include three degrees of freedom in XYZ directions.

In accordance with Aspect 7 of one or more embodiments, in the bridge beam of Aspect 6, the Z direction may be a thickness direction of the main body portion; and the first actuator may be capable of adjusting a relative distance between the optical probe and the semiconductor device in the Z direction.

In accordance with Aspect 8 of one or more embodiments, in the bridge beam of Aspect 6 or 7, the first actuator may include six degrees of freedom in the XYZ directions, a roll direction, a pitch direction, and a yaw direction.

In accordance with Aspect 9 of one or more embodiments, in the bridge beam of any one of Aspects 1 to 8, the bridge beam may be detachably attached to the semiconductor device handling apparatus.

In accordance with Aspect 10 of one or more embodiments, in the bridge beam of any one of Aspects 1 to 9, the first actuator may align the optical probe with respect to the semiconductor device.

In accordance with Aspect 11 of one or more embodiments, in the bridge beam of Aspect 10, the first actuator may include a third actuator that performs coarse alignment of the optical probe with respect to the semiconductor device; and a fourth actuator that performs fine alignment of the optical probe with respect to the semiconductor device after the coarse alignment is completed.

Aspect 12 of one or more embodiments is a semiconductor device handling apparatus that handles a semiconductor device. The semiconductor device handling apparatus includes the bridge beam according to any one of Aspects 1 to 11.

In accordance with Aspect 13 of one or more embodiments, in the semiconductor device handling apparatus of Aspect 12, the semiconductor device handling apparatus may further include the probe card that is attached to the bridge beam and has a contact for electrically connecting with a terminal of the semiconductor device.

In accordance with Aspect 14 of one or more embodiments, in the semiconductor device handling apparatus of Aspect 12 or 13, the semiconductor device handling apparatus may further include a moving device that moves the semiconductor device to bring the terminal and the contact into contact with each other, and presses the semiconductor device against the probe card; a base portion that supports the moving device; and a support frame that is provided on the base portion and supports the bridge beam.

In accordance with Aspect 15 of one or more embodiments, in the semiconductor device handling apparatus of Aspect 14, the first actuator may align the optical probe with the semiconductor device by moving the optical probe relative to the semiconductor device while the moving device is pressing the semiconductor device against the probe card.

In accordance with Aspect 16 of one or more embodiments, in the semiconductor device handling apparatus of any one of Aspects 12 to 15, the bridge beam may further include an optical detection portion that detects the optical signal emitted from the optical probe and outputs a detection result; and the semiconductor device handling apparatus may include a calculation device that calculates an intensity of the optical signal based on the detection result output from the optical detection portion.

In accordance with Aspect 17 of one or more embodiments, in the semiconductor device handling apparatus of Aspect 16, the calculation device may determine that the optical probe is normal when the detection result output from the optical detection portion is within a predetermined range of light intensity.

Aspect 18 of one or more embodiments is a semiconductor device testing apparatus that tests a semiconductor device. The semiconductor device testing apparatus includes the semiconductor device handling apparatus according to any one of Aspects 12 to 17; the probe card; and a tester to which the probe card is electrically connected, the tester testing the semiconductor device.

According to one or more embodiments, by a main body portion with a first actuator for moving an optical probe relative to a semiconductor device, the relative positional relationship between the optical probe and the semiconductor device can be adjusted independently. Therefore, it is possible for the optical probe to be positioned with high precision relative to the semiconductor device. In addition, in one or more embodiments, a function for positioning the optical probe with high precision relative to the semiconductor device can be added to a semiconductor device testing apparatus without making major modifications to the semiconductor device testing apparatus.

### BRIEF DESCRIPTION OF THE DRAWINGS

FIG. 1 is a cross-sectional view illustrating an example of a semiconductor device testing apparatus when a semiconductor wafer and a probe card are separated from each other in one or more embodiments.

FIG. 2 is a cross-sectional view illustrating an example of a semiconductor device testing apparatus when a semiconductor wafer is pressed against a probe card in one or more embodiments.

FIG. 3 is an enlarged cross-sectional view of a portion III in FIG. 1.

FIG. 4 is a block diagram illustrating an outline of a semiconductor device testing apparatus in one or more embodiments.

FIG. 5 is an enlarged cross-sectional view illustrating a modification of a bridge beam in one or more embodiments.

### DESCRIPTION OF THE EMBODIMENTS

Hereinafter, embodiments will be described based on the drawings.

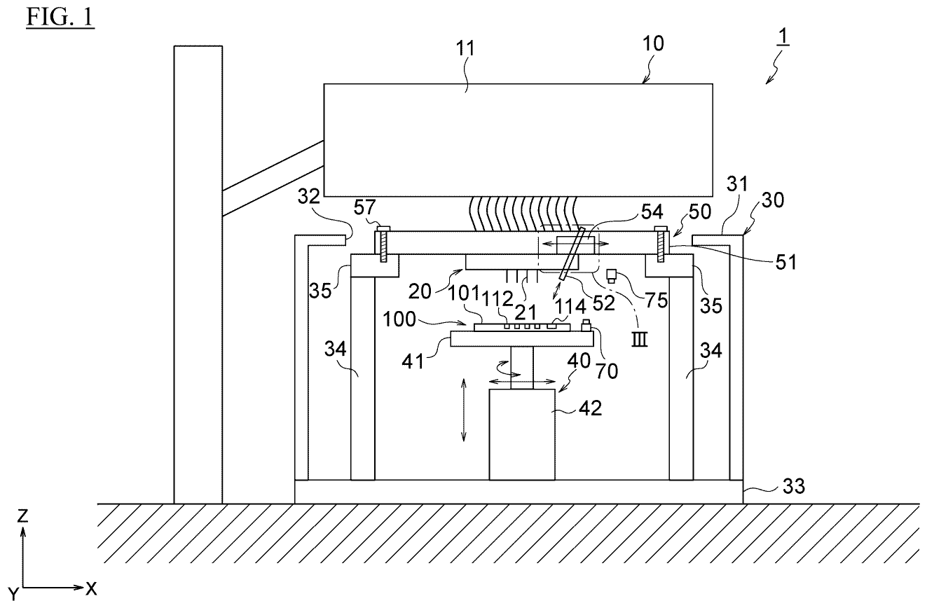

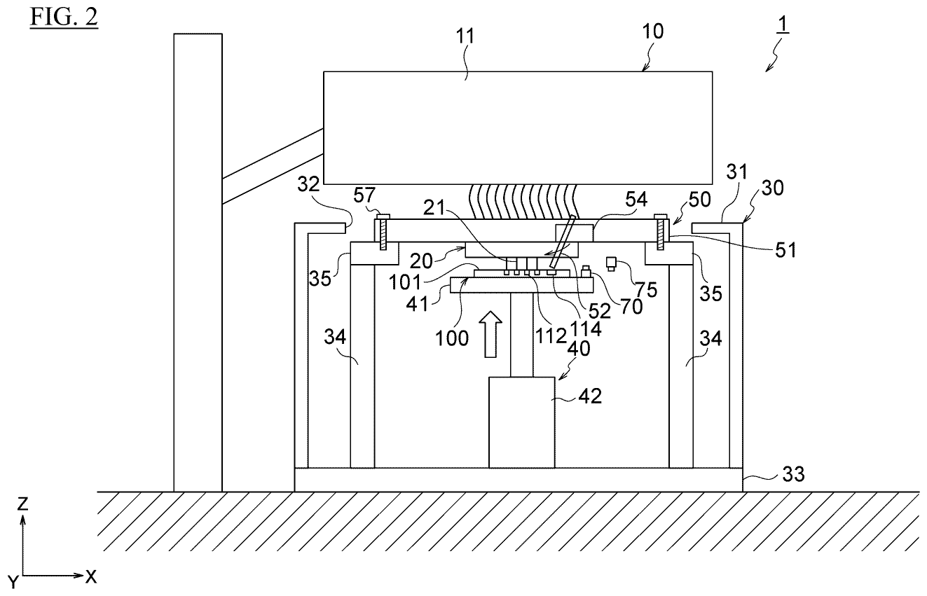

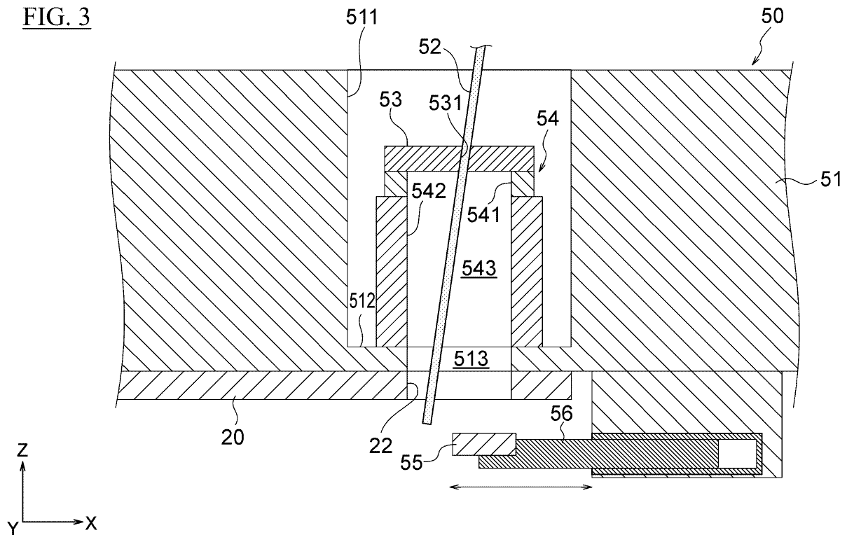

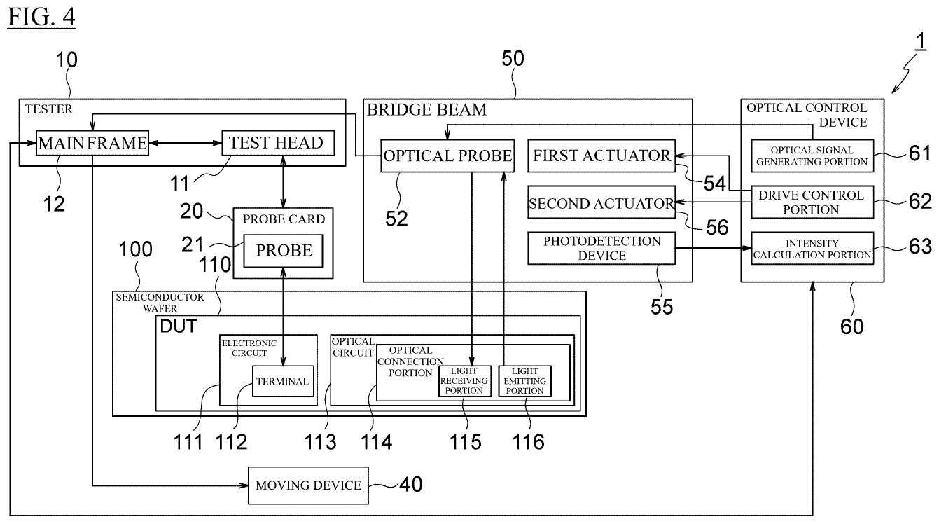

FIG. 1 is a cross-sectional view illustrating an example of a semiconductor device testing apparatus 1 when a semiconductor wafer 100 and a probe card 20 are separated from each other in one or more embodiments. FIG. 2 is a cross-sectional view illustrating an example of the semiconductor device testing apparatus 1 when the semiconductor wafer 100 is being pressed against the probe card 20 in one or more embodiments. FIG. 3 is an enlarged cross-sectional view of a portion III in FIG. 1. FIG. 4 is a block diagram illustrating an outline of the semiconductor device testing apparatus 1 in one or more embodiments.

As illustrated in FIGS. 1 and 4, the semiconductor device testing apparatus 1 in one or more embodiments is an apparatus for testing a DUT 110 (see FIG. 4) built into the semiconductor wafer 100. The semiconductor device testing apparatus 1 includes a tester 10, the probe card 20, a wafer prober 30, and an optical control device 60. The DUT 110 corresponds to an example of a “semiconductor device” according to an aspect of one or more embodiments, and the wafer prober 30 corresponds to an example of a “semiconductor device handling apparatus” according to an aspect of one or more embodiments.

As illustrated in FIG. 4, the DUT 110 is formed on the semiconductor wafer 100. Note that in FIG. 4, for the sake of convenience, one DUT 110 is formed on the semiconductor wafer 100, but in reality, a plurality of DUTs 110 are formed on the semiconductor wafer 100.

Each DUT 110 that is a test target of the semiconductor device testing apparatus 1 is a device capable of handling electrical and optical signals, and is a composite circuit element that includes an electronic circuit 111 and an optical circuit 113. The electronic circuit 111 is a circuit that operates based on an electric signal, and has terminals 112 for inputting and outputting electric signals. As illustrated in FIG. 1, the terminals 112 are arranged on an upper surface 101 of the semiconductor wafer 100.

On the other hand, as illustrated in FIG. 4, the optical circuit 113 is a circuit that operates based on an optical signal or an electrical signal generated from a received optical signal, and is formed using, for example, silicon photonics technology. The optical circuit 113 includes an optical connection portion 114 for inputting and outputting optical signals. As illustrated in FIG. 1, the optical connection portion 114 is arranged on the upper surface 101 of the semiconductor wafer 100, similar to the terminals 112 described above. As illustrated in FIG. 4, the optical connection portion 114 in one or more embodiments includes, but is not particularly limited to, a light receiving portion 115 that receives an optical signal and a light emitting portion 116 that emits an optical signal. Specific examples of such a light receiving portion 115 and light emitting portion 116 are not particularly limited, but may include, for example, a grating coupler or the like.

When testing the DUT 110, electrical signals are input and output to and from the electronic circuit 111 via the terminals 112, and optical signals are input and output to and from the optical circuit 113 via the optical connection portion 114. For example, after the test is completed, the semiconductor wafer 100 is diced to separate the DUTs 110, and the separate DUTs 110 are attached on a substrate and connected to optical fibers to become the final product. This final product is not particularly limited; however, may be, for example, a co-packaged optics (CPO) device or the like.

Note that the DUT 110 to be tested by the semiconductor device testing apparatus 1 of one or more embodiments may be a bare die including the electronic circuit 111 and the optical circuit 113. That is, the DUT 110 to be tested may be a single die before being attached on a substrate.

The tester 10 is a testing apparatus that tests a DUT 110 using electrical signals and optical signals, and as illustrated in FIG. 1, includes a test head 11 and a main frame (tester body) 12 (see FIG. 4), and the test head 11 is connected to the main frame 12 via a cable.

The probe card 20 is electrically connected to the test head 11. The probe card 20 enters an inner portion of the wafer prober 30 through an opening 32 formed in an upper base 31 of the wafer prober 30. The probe card 20 is fixed relative to the wafer prober 30.

The probe card 20 includes a plurality of probes 21 attached on a wiring board. The probes 21 are electric probes that come into contact with the terminals 112 of the DUT 110 on the semiconductor wafer 100. The plurality of probes 21 are arranged to correspond to a plurality of terminals 112 of one DUT 110 on the semiconductor wafer 100. These probes 21 correspond to an example of a “contact” in an aspect of one or more embodiments.

Although not limited to this, specific examples of the probe 21 include a pogo pin, a vertical probe needle, a cantilever probe needle, an anisotropic conductive rubber sheet, a bump on a membrane, or a contactor fabricated using MEMS technology.

As illustrated in FIGS. 1 and 2, the wafer prober 30 includes a moving device 40 and a bridge beam 50. The moving device 40 is a device that holds the semiconductor wafer 100 and moves the semiconductor wafer 100. The moving device 40 is supported by a lower base 33. The lower base 33 corresponds to an example of a “base portion” in an aspect of one or more embodiments.

The moving device 40 includes a holding portion 41 and a moving portion 42. The semiconductor wafer 100 is placed on the holding portion 41, and the holding portion 41 holds the semiconductor wafer 100. Although not particularly limited, the semiconductor wafer 100 may be held on a wafer tray or the like, and by fixing the wafer tray to the holding portion 41, the semiconductor wafer 100 is indirectly held by the holding portion 41.

The moving portion 42 can move in the X direction, the Y direction, and the Z direction in the figure, and can also rotate around the Z-axis. The moving portion 42 is installed on the lower base 33 of the wafer prober 30 so that the holding portion 41 faces the probes 21 of the probe card 20 in the Z-axis direction in the figure. As illustrated in FIG. 2, when the moving portion 42 raises the holding portion 41, the terminals 112 of the DUT 110 and the probes 21 come into contact with each other, and the tip end of the optical probe 52 faces the optical connection portion 114 of the DUT 110.

Although not particularly limited, the moving portion 42 includes, for example, an actuator, a transmission mechanism, and a guide mechanism. Although not particularly limited, specific examples of the actuator include a motor including an electric motor (a rotary motor, a linear motor, and the like) and an electric actuator including the electric motor or the like, a specific example of the transmission mechanism includes a ball screw mechanism, and a specific example of the guide mechanism includes a linear guide mechanism including a guide rail and a block that can slide on the guide rail.

As illustrated in FIGS. 1 and 2, the probe card 20 is attached to a lower surface of the bridge beam 50. The bridge beam 50 is a beam-shaped member for receiving a reaction force from the probes 21 when the semiconductor wafer 100 and the probe card 20 are brought into contact with each other by the wafer prober 30.

In one or more embodiments, the bridge beam 50 is indirectly supported by a support frame 34 via a pair of inclination adjustment mechanisms 35 of the wafer prober 30. The pair of inclination adjustment mechanisms 35 are mechanisms for adjusting the inclination of the bridge beam 50, and the bridge beam 50 is bridged between the pair of inclination adjustment mechanisms 35. The bridge beam 50 is detachably attached to the inclination adjustment mechanisms 35 by bolt screws 57.

In this manner, in one or more embodiments, the bridge beam 50 is detachably attached to the wafer prober 30. Therefore, by preparing a plurality of types of bridge beams 50 in advance, when the probe card 20 is replaced according to the type of DUT 110, for example, the bridge beam 50 can also be replaced with one corresponding to that probe card 20. Therefore, the bridge beam 50 may be sold on the market by itself, independent of the wafer prober 30.

The support frame 34 supports the inclination adjustment mechanisms 35 from below. The support frame 34 stands on the lower base 33 and is supported by the lower base 33 from below. Note that in one or more embodiments, the bridge beam 50 is indirectly supported by the support frame 34, but not limited. The bridge beam 50 may be attached to the support frame 34 and may be supported directly by the support frame 34.

As illustrated in FIG. 3, the bridge beam 50 includes a main body portion 51, an optical probe 52, a holder 53, a first actuator 54, a photodetection device 55, and a second actuator 56.

As illustrated in FIGS. 1 and 2, the main body portion 51 is a beam-shaped member that spans between the pair of inclination adjustment mechanisms 35. As illustrated in FIG. 3, the main body portion 51 is formed with a bottomed accommodation hole 511 for accommodating the holder 53 and the first actuator 54. An opening 513 penetrating a bottom portion 512 is formed in the bottom portion 512 of the accommodation hole 511. This opening 513 communicates with an opening 22 of the probe card 20.

The optical probe 52 in one or more embodiments is inserted through the accommodation hole 511 of the bridge beam 50 and the opening 22 of the probe card 20. The optical probe 52 emits optical signals transmitted from an optical signal generating portion 61 of the optical control device 60 (see FIG. 4) described later to the optical connection portion 114 of the DUT 110, and also receives optical signals output from the optical connection portion 114.

More specifically, as illustrated in FIG. 4, the optical probe 52 in one or more embodiments emits optical signals transmitted from the optical signal generating portion 61 to the light receiving portion 115 of the DUT 110. In addition, the optical probe 52 receives optical signals emitted from the light emitting portion 116 of the DUT 110 and transmits the optical signals to the main frame 12.

Such an optical probe 52 is not particularly limited, but may be, for example, an optical fiber cable having a plurality of optical fibers or the like. Furthermore, the optical probe 52 may further include optical elements such as a mirror in addition to the optical fiber cable.

As illustrated in FIG. 3, the optical probe 52 is held by a holder 53. The holder 53 in one or more embodiments is attached to the first actuator 54 and fixes the position of the optical probe 52 relative to the first actuator 54. The holder 53 in one or more embodiments has a holding hole 531. The optical probe 52 is inserted into the holding hole 531 and is held by an inner wall of the holding hole 531.

Note that in one or more embodiments, the holder 53 is exemplified as a holder that holds the optical probe 52 via the holding hole 531, but is not limited to this, and various fixing devices can be used as the holder 53. For example, the holder 53 may be a clip, a clamp, or the like capable of clamping and fixing the optical probe 52.

In addition, the position of the optical connection portion 114 of the DUT 110 changes depending on the type of the DUT 110; however, the change in the position of the optical connection portion 114 can be accommodated by changing the type of holder 53 depending on the type of the DUT 110.

The holder 53 is fixed to the first actuator 54. The first actuator 54 is an electric actuator that moves the optical probe 52 fixed to the holder 53 relative to the DUT 110.

The first actuator 54 includes a mounting stage 541 and a driving portion 542. The mounting stage 541 is a stage for fixing the holder 53. The driving portion 542 moves the mounting stage 541 based on a control signal from a drive control portion 62 (see FIG. 4) that will be described later.

The driving portion 542 in one or more embodiments is capable of, but is not limited to, moving the mounting stage 541 in the X direction, the Y direction, the Z direction, the roll direction, the pitch direction, and the yaw direction. That is, the first actuator 54 in one or more embodiments has six degrees of freedom. An example of such a first actuator 54 is an actuator such as SmarPod manufactured by SmarAct or the like. However, the first actuator 54 is not limited to this. The first actuator 54 only needs to be provided with a motor, a transmission mechanism, and a guide mechanism in the driving portion 542. The driving portion 542 needs to have at least three degrees of freedom in the X direction, the Y direction, and the Z direction.

The first actuator 54 has an insertion hole 543 that penetrates through the mounting stage 541 and the driving portion 542. The insertion hole 543 communicates with the holding hole 531 of the holder 53 and the opening 513 of the main body portion 51, and the optical probe 52 passes through the inside of the insertion hole 543. Note that in one or more embodiments, the optical probe 52 is inserted through the accommodation hole 511 of the bridge beam 50 and the opening 22 of the probe card 20, but not limited.

The photodetection device 55 detects the optical signal emitted from the optical probe 52 and outputs the detection result. The photodetection device 55 is provided to measure the intensity of the optical signal emitted from the optical probe 52, and the photodetection device 55 transmits the detection result to an intensity calculation portion 63 of the optical control device 60 (see FIG. 4) described later. An example of such a photodetection device 55 is a photodetector or the like. The photodetection device 55 corresponds to an example of an “optical detection portion” in an aspect of one or more embodiments.

The photodetection device 55 is fixed to the second actuator 56. The second actuator 56 in one or more embodiments is provided in the main body portion 51. The second actuator 56, by moving the photodetection device 55 relative to the optical probe 52, moves the photodetection device 55 to a position where the photodetection device 55 can receive an optical signal. In addition, during testing of the DUT 110 or similar situations, the photodetection device 55 is removed and moved to a position where the photodetection device 55 does not receive optical signals. Such a second actuator 56 is not particularly limited, but may be, for example, an air cylinder or the like.

As illustrated in FIG. 4, the optical control device 60 is optically connected to the optical probe 52 and the photodetection device 55, and is electrically connected to the first and second actuators 54, 56 and the main frame 12. The optical control device 60 includes the optical signal generating portion 61, the drive control portion 62, and the intensity calculation portion 63. The intensity calculation portion 63 corresponds to an example of a “calculation device” in an aspect of one or more embodiments.

The optical signal generating portion 61 transmits an optical signal for testing to the light receiving portion 115 of the DUT 110 via the optical probe 52. The optical signal generating portion 61 is not particularly limited, but examples thereof include light emitting elements such as LD and LED that are driven by a signal from a pattern generator or the like. This optical signal generating portion 61 may generate an optical signal based on a signal from the tester 10 (such as a signal from the test head 11 or a signal from the main frame 12), although this is not particularly limited.

The drive control portion 62 controls the first actuator 54 and the second actuator 56. Details will be described later; however, in one or more embodiments, the drive control portion 62 controls the first actuator 54 to align the optical probe 52 with the DUT 110 by moving the optical probe 52 relative to the DUT 110 when the moving device 40 is pressing the DUT 110 against the probe card 20, as illustrated in FIG. 2.

On the other hand, as illustrated in FIG. 3, the drive control portion 62 controls the second actuator 56 so as to move the photodetection device 55 to a position where the photodetection device 55 can receive an optical signal. The control of the second actuator 56 by the drive control portion 62 is executed, although not limited to, when the type of the DUT 110 is changed or every time testing is performed a predetermined number of times (for example, 1000 times).

As illustrated in FIG. 4, the intensity calculation portion 63 calculates the intensity of the optical signal based on the detection result of the photodetection device 55. Then, in a case in which the detection result output from the photodetection device 55 is a light intensity within a predetermined range, the intensity calculation portion 63 determines that the optical probe 52 is normal, and, in a case in which the detection result is a light intensity outside the predetermined range, determines that the optical probe 52 is abnormal. More specifically, a case in which the optical probe 52 is normal is, for example, a case in which the optical probe 52 is clean, a case in which the optical probe 52 is not broken, or the like. On the other hand, a case in which the optical probe 52 is abnormal may be, for example, a case in which a foreign object attached to the optical probe 52 blocks the optical signal, a case in which the optical probe 52 is broken, or the like.

The drive control portion 62 and the intensity calculation portion 63 are configured, for example, by a computer. Although not specifically illustrated, the computer is an electronic computer equipped with a CPU (processor), a main memory device (such as a RAM), an auxiliary memory device (such as a hard disk or SSD), an interface, or the like. The above-mentioned control is functionally achieved, for example, by the drive control portion 62 and the intensity calculation portion 63 executing a program. Note that the drive control portion 62 and the intensity calculation portion 63 may be configured by a circuit board instead of a computer.

A method for pressing the DUT 110 against the probe card 20 by the above-mentioned wafer prober 30 will be described below. First, before operating the moving device 40, the relative positional relationship between the probes 21 and the optical probe 52 is measured based on image information captured by a first camera 70. Based on the measurement result, the position of the optical probe 52 is adjusted by the first actuator 54 so that the positional relationship between the probes 21 and the optical probe 52 coincides with the positional relationship (design value) between the terminals 112 of the DUT 110 and the optical connection portion 114. In this way, by previously adjusting the positional relationship between the probes 21 and the optical probe 52 to be the same as the positional relationship between the terminals 112 and the optical connection portion 114, it is possible to reduce the search range and search time based on the light intensity as described below.

Next, the semiconductor wafer 100 is fixed to the holding portion 41 of the moving device 40, and the relative positional relationship between the probes 21 and the terminals 112 is measured based on the image information captured by a second camera 75.

Next, based on the relative positional relationship between the probes 21 and the terminals 112, the tester 10 controls the moving device 40 to move the semiconductor wafer 100 to a position where the probes 21 and the terminals 112 face each other. That is, the semiconductor wafer 100 is aligned with respect to the probe card 20 so that the probes 21 and the terminals 112 face each other.

Then, the moving device 40, by lifting the semiconductor wafer 100, presses the semiconductor wafer 100 against the probe card 20, causing the probes 21 to come into contact with the terminals 112. At this time, as illustrated in FIG. 2, the optical connection portion 114 and the optical probe 52 are spaced apart from each other.

Next, the drive control portion 62 controls the first actuator 54 to align the optical connection portion 114 and the optical probe 52. Although not particularly limited, the relative positional relationship between the optical connection portion 114 and the optical probe 52 is recognized based on, for example, the intensity of the light output from the optical connection portion 114. More specifically, light output from the optical signal generating portion 61 of the optical control device 60 (see FIG. 4) is irradiated from the optical probe 52 toward the upper surface 101 of the semiconductor wafer 100 including the optical connection portion 114. Then, the light output from the optical connection portion 114 via a loopback circuit incorporated in the optical circuit of the DUT 110 is acquired by the optical probe 52. While this operation is being performed, the drive control portion 62 of the optical control device 60 (see FIG. 4), by the first actuator 54, causes the optical probe 52 to scan along the upper surface 101 of the semiconductor wafer 100. The tester 10 then measures the intensity of the light output from the optical connection portion 114, and the drive control portion 62, by stopping the movement of the optical probe 52 at a position where the intensity of the light reaches or exceeds a predetermined value, positions the optical probe 52 with respect to the optical connection portion 114.

In addition, the alignment in one or more embodiments may include moving the optical probe 52 in the Z direction (thickness direction of the main body portion). The probes 21 of the probe card 20 are deformed by being contracted by the terminals 112; however, since the probes 21 gradually wear out, the amount of deformation (amount of overdrive) changes depending on the number of tests performed. Accordingly, the position of the semiconductor wafer 100 in the Z direction during testing changes depending on the number of times the test is performed. In contrast, since the first actuator 54 in one or more embodiments has a degree of freedom in the Z direction, the relative position of the optical probe 52 and the optical connection portion 114 in the Z direction can be aligned for each test.

As described above, in one or more embodiments, in addition to the moving device 40 capable of changing the relative position between the terminals 112 and the probes 21, the first actuator 54 capable of changing the relative position between the optical connection portion 114 and the optical probe 52 is provided on the bridge beam 50. Therefore, the relative positional relationship between the DUT 110 and the optical probe 52 can be adjusted independently, and the positioning accuracy of the optical probe 52 with respect to the DUT 110 can be improved.

In addition, in one or more embodiments, since the optical probe 52, the first actuator 54, or the like are provided on the bridge beam 50, it is possible to add to the semiconductor device testing apparatus 1 a function of moving the optical probe 52 independently and positioning the optical probe 52 with high precision relative to the DUT 110 without making major modifications to the semiconductor device testing apparatus 1.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

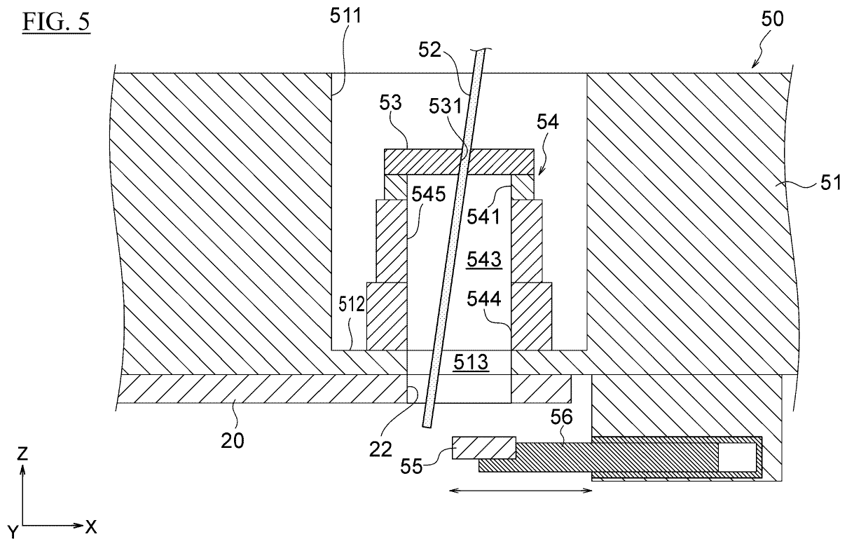

For example, the first actuator 54 in the above embodiments may have a structure capable of performing coarse alignment and fine alignment, as illustrated in FIG. 5. FIG. 5 is an enlarged cross-sectional view illustrating a modification of the bridge beam 50 in one or more embodiments.

As illustrated in FIG. 5, the first actuator 54 in this modification has a third actuator 544 and a fourth actuator 545. The third actuator 544 is placed on the bottom portion 512 of the accommodation hole 511. The third actuator 544 is an actuator that performs coarse alignment of the optical probe 52 with respect to the DUT 110. This coarse alignment provides approximate positioning of the optical probe 52 with respect to the DUT 110. An example of the third actuator 544 is an electric actuator equipped with a general electric motor.

The fourth actuator 545 is fixed to the third actuator 544. The fourth actuator 545 is an actuator that performs fine alignment of the optical probe 52 with respect to the DUT 110 and moves the optical probe 52 more precisely than the third actuator 544. This fine alignment positions the optical probe 52 with respect to the DUT 110 with high precision. The fourth actuator 545 is not particularly limited; however, may be, for example, an impact drive type motor equipped with an ultrasonic motor or the like.

In such a modification, the optical probe 52 can be coarsely aligned to the DUT 110 by the third actuator 544, and then the optical probe 52 can be finely aligned to the DUT 110 by the fourth actuator 545, thereby enabling alignment to be performed with greater precision.

Further, although the bridge beam 50 in the above embodiments includes one optical probe 52, it is not limited to this and the bridge beam 50 may include a plurality of optical probes 52.

### EXPLANATIONS OF LETTERS OR NUMERALS

1 . . . Semiconductor device testing apparatus
10 . . . Tester
11 . . . Test head
12 . . . Main frame
20 . . . Probe card
21 . . . Probe
22 . . . Opening
30 . . . Wafer prober
31 . . . Upper base
32 . . . Opening
33 . . . Lower base
34 . . . Support frame
35 . . . Inclination adjustment mechanism
40 . . . Moving device
41 . . . Holding portion
42 . . . Moving portion
50 . . . Bridge beam
51 . . . Main body portion (beam-shaped main body)
511 . . . Accommodation hole
512 . . . Bottom portion
513 . . . Opening
52 . . . Optical probe
53 . . . Holder
531 . . . Holding hole
54 . . . First actuator
541 . . . Mounting stage
542 . . . Driving portion
543 . . . Insertion hole
544 . . . Third actuator (drive mechanism)
545 . . . Fourth actuator (additional drive mechanism)
55 . . . Photodetection device (optical detector)
56 . . . Second actuator
57 . . . Bolt screw
60 . . . Optical control device
61 . . . Optical signal generating portion
62 . . . Drive control portion
63 . . . Intensity calculation portion
70 . . . First camera
75 . . . Second camera
100 . . . Semiconductor wafer
101 . . . Upper surface
110 . . . DUT
111 . . . Electronic circuit
112 . . . Terminal
113 . . . Optical circuit
114 . . . Optical connection portion
115 . . . Light receiving portion
116 . . . Light emitting portion

What is claimed is:

1. A bridge beam attached to a semiconductor device handling apparatus that handles a semiconductor device, comprising:
a beam-shaped main body to which a probe card is attached, wherein the probe card has a contact that is electrically connected to a terminal of the semiconductor device; and
a first actuator, attached to the beam-shaped main body, that moves an optical probe relative to the semiconductor device, wherein the optical probe performs one or both of emitting an optical signal to the semiconductor device and receiving the optical signal from the semiconductor device.

2. The bridge beam according to claim 1 further comprising a holder, attached to the first actuator, that holds the optical probe.

3. The bridge beam according to claim 1, wherein
the optical probe emits the optical signal, and
the bridge beam further comprises an optical detector that detects the emitted optical signal and outputs a detection result to a calculation device that calculates an intensity of the optical signal based on the detection result.

4. The bridge beam according to claim 3 further comprising:
a second actuator that moves the optical detector relative to the optical probe such that the optical detector receives the optical signal.

5. The bridge beam according to claim 1 further comprising the optical probe.

6. The bridge beam according to claim 1, wherein the first actuator has three degrees of freedom in three directions.

7. The bridge beam according to claim 6, wherein the first actuator adjusts a relative distance between the optical probe and the semiconductor device in a thickness direction of the beam-shaped main body.

8. The bridge beam according to claim 1, wherein the bridge beam is detachably attached to the semiconductor device handling apparatus.

9. The bridge beam according to claim 1, wherein the first actuator:
aligns the optical probe with respect to the semiconductor device, and includes:
a drive mechanism that aligns the optical probe with respect to the semiconductor device; and
an additional mechanism that aligns the optical probe with respect to the semiconductor device more precisely than the drive mechanism.

10. A semiconductor device handling apparatus that handles the semiconductor device, comprising the bridge beam according to claim 1.

11. The semiconductor device handling apparatus according to claim 10, further comprising the probe card.

12. The semiconductor device handling apparatus according to claim 10, further comprising:
a moving device that moves the semiconductor device to contact the terminal with the contact and presses the semiconductor device against the probe card;
a base that supports the moving device; and
a support frame, disposed on the base, that supports the bridge beam.

13. The semiconductor device handling apparatus according to claim 12, wherein the first actuator moves the optical probe to align the optical probe with the semiconductor device while the moving device presses the semiconductor device against the probe card.

14. The semiconductor device handling apparatus according to claim 10, wherein
the optical probe emits the optical signal,
the bridge beam further includes an optical detector that detects the emitted optical signal and outputs a detection result, and
the semiconductor device handling apparatus further comprises a calculation device that calculates an intensity of the optical signal based on the detection result.

15. The semiconductor device handling apparatus according to claim 14, wherein the calculation device determines that the optical probe is normal when the detection result is within a predetermined range of light intensity.

16. A semiconductor device testing apparatus that tests the semiconductor device, comprising:
the semiconductor device handling apparatus according to claim 10;
the probe card; and
a tester that is electrically connected to the probe card and tests the semiconductor device.
